(19) United States
(12) Patent Application Publication
(10) Pub. No.: US 2013/0094317 A1
(43) Pub. Date: Apr. 18, 2013

(54) REFRESH CONTROL CIRCUIT AND METHOD OF SEMICONDUCTOR APPARATUS

(71) Applicant: Jeong Woo LEE, Icheon-si Gyeonggi-do (KR)

(72) Inventor: Jeong Woo LEE, Icheon-si Gyeonggi-do (KR)

(73) Assignee: SK HYNIX INC., Icheon-si Gyeonggi-do (KR)

(21) Appl. No.: 13/602,066

(22) Filed: Aug. 31, 2012

(30) Foreign Application Priority Data
Oct. 18, 2011 (KR) 10-2011-0106162

(51) Int. Cl. G11C 11/402

(52) U.S. Cl. 365/222

(57) ABSTRACT

A refresh control circuit of a semiconductor apparatus includes: a first bank refresh counter configured to increase or decrease a logic value of a first refresh address signal when a first bank address signal is enabled during a refresh operation, a second bank refresh counter configured to increase or decrease a logic value of a second refresh address signal when a second bank address signal is enabled during the refresh operation, a bank selection unit configured to generate first and second bank select signals in response to the first and second bank address signals during the refresh operation, and a row selection unit configured to generate first and second row select signals in response to the first and second refresh address signals and the first and second bank select signals.

### CROSS-REFERENCES TO RELATED APPLICATION

The present application claims priority under 35 U.S.C. §119(a) to Korean application number 10-2011-0106162, filed on Oct. 18, 2011, in the Korean Intellectual Property Office, which is incorporated herein by reference in its entirety.

### BACKGROUND

1. Technical Field

The present invention relates to a semiconductor apparatus, and more particularly, to a semiconductor apparatus performing a refresh operation.

2. Related Art

Among semiconductor apparatuses, a memory apparatus such as DRAM includes a memory cell implemented with a capacitor. Since a leakage current inevitably occurs in the capacitor due to the characteristics of the capacitor, DRAM exhibits characteristics of a volatile memory apparatus. Therefore, the memory apparatus should periodically perform a data retention operation after storing data in the memory cell. The data retention operation is referred to as a refresh operation. In general, the refresh operation is divided into an auto refresh operation, which is performed according to a command input, and a self refresh operation, which is periodically performed by the memory apparatus itself.

FIG. 1 schematically illustrates the configuration of a conventional refresh control circuit. In FIG. 1, the conventional refresh control circuit includes a circuit for a normal operation of a semiconductor apparatus and a circuit for a refresh operation. The refresh control circuit includes an address latch unit 10, a refresh counter 20, an address selection unit 30, an activation control unit 40, first to fourth bank selection units 51 to 54, and a row selection unit 60. The address latch unit 10 is configured to receive a row address signal RA and an active signal ACT to generate a normal address signal Normal_Gax. The refresh counter 20 is configured to receive a refresh signal REFP to generate a refresh address signal Ref_Gax having a logic value which successively increases or decreases when the refresh signal REFP is inputted. The address selection unit 30 is configured to select either the normal address signal Normal_Gax or the refresh address signal Ref_Gax as the output address signal Gax in response to a refresh command REF. The activation control unit 40 is configured to receive the active signal ACT and the refresh signal REFP to generate an activation control signal ACTCON when either one of the active signal ACT or refresh signal REFP is enabled.

The first to fourth bank selection units 51 to 54 are configured to receive the activation control signal ACTCON and allocated bank address signals BA<0:3>, respectively. Furthermore, the first to fourth bank selection units 51 to 54 are configured to receive the refresh signal REFP. The first to fourth bank selection units 51 to 54 generate first to fourth bank select signals ACT_BK0 to ACT_BK3, respectively. The refresh signal REFP is disabled during a normal operation and enabled during a refresh operation. The first to fourth bank selection units 51 to 54 enable only specific bank select signals ACT_BK0 to ACT_BK3 according to the bank address signals BA<0:3>, respectively, during the normal operation. For example, when the first bank address signal BA<0> is at a high level and the second to fourth bank address signals BA<1:3> are all at low levels, the first bank selection unit 51 may enable the first bank select signal ACT_BK0, and the second to fourth bank selection units 52 to 54 may disable the second to fourth bank select signals ACT_BK1 to ACT_BK3, respectively. The first to fourth bank selection units 51 to 54 enable all of the first to fourth bank select signals ACT_BK0 to ACT_BK3 in response to the refresh signal REFP during the refresh operation. In other words, the first to fourth bank selection units 51 to 54 are configured to enable all of the first to fourth bank select signals ACT_BK0 to ACT_BK3 regardless of the bank address signals BA<0:3> during the refresh operation.

The row selection unit 60 is configured to receive the output address signal Gax and the first to fourth bank select signals ACT_BK0 to ACT_BK3 to generate first to fourth row select signals Row_BK0 to Row_BK3. The first to fourth row select signals Row_BK0 to Row_BK3 serve to enable word lines of the corresponding memory banks.

The conventional refresh control circuit is configured to enable the word lines in all of the memory banks during the refresh operation. Therefore, the refresh operation is performed on all of the memory banks at the same time.

### SUMMARY

A refresh control circuit and method capable of controlling a refresh operation to be separately performed for each memory bank is described herein.

In one embodiment of the present invention, a refresh control circuit of a semiconductor apparatus includes: a first bank refresh counter configured to increase or decrease a logic value of a first refresh address signal when a first bank address signal is enabled during a refresh operation, a second bank refresh counter configured to increase or decrease a logic value of a second refresh address signal when a second bank address signal is enabled during the refresh operation, a bank selection unit configured to generate first and second bank select signals in response to the first and second bank address signals during the refresh operation, and a row selection unit configured to generate first and second row select signals in response to the first and second refresh address signals and the first and second bank select signals.

In another embodiment of the present invention, during a normal operation, the refresh control circuit enables word lines of a specific memory bank in response to a bank address signal and a row address signal. During a refresh operation, the refresh control circuit selects a specific memory bank in response to the bank address signal, by enabling word lines included in the selected memory bank in response to a refresh address signal.

In another embodiment of the present invention, a refresh control method of a semiconductor apparatus includes the steps of: generating a refresh address signal for a specific memory bank among a plurality of memory banks in response to a bank address signal during a refresh operation, enabling a bank select signal for the specific memory bank in response to the bank address signal during the refresh operation, and combining the refresh address signal and the bank select signal for generating a row address signal.

### BRIEF DESCRIPTION OF THE DRAWINGS

Features, aspects, and embodiments are described in conjunction with the attached drawings, in which:

FIG. 1 schematically illustrates the configuration of a refresh control circuit of a conventional semiconductor memory apparatus, and

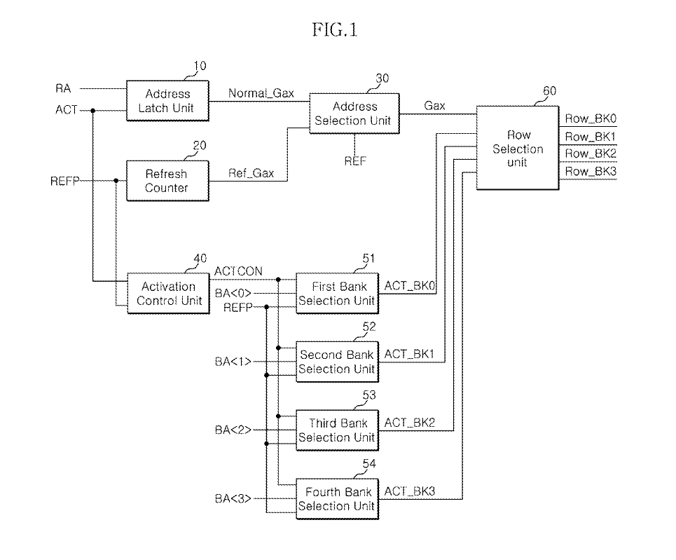

FIG. 2 schematically illustrates the configuration of a refresh control circuit of a semiconductor apparatus according to one embodiment.

### DETAILED DESCRIPTION

Hereinafter, a refresh control circuit and method of a semiconductor apparatus according to the present invention will be described below with reference to the accompanying drawings through various embodiments.

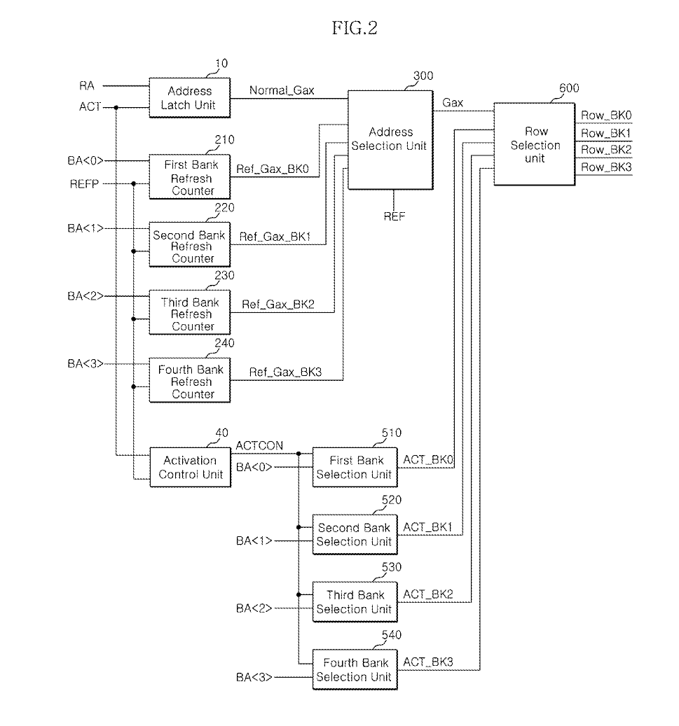

FIG. 2 schematically illustrates the configuration of a refresh control circuit of a semiconductor apparatus according to one embodiment. In FIG. 2, the refresh control circuit includes first to fourth bank refresh counters 210 to 240, first to fourth bank selection units 510 to 540, and a row selection unit 600. FIG. 2 illustrates that the semiconductor apparatus according to the embodiment includes four memory banks. However, the numbers of bank refresh counters and bank selection units may be increased or decreased according to the number of memory banks desired. Similarly, the number of bank address signals may also be increased or decreased based on the number of memory banks, and each of the bank address signals in this embodiment of the present invention is defined as a signal for selecting a memory bank which is designated in the same manner as a designated number.

The refresh control circuit includes the first to fourth bank refresh counters 210 to 240 allocated to the respective memory banks. The first bank refresh counter 210 is configured to receive a refresh signal REFP and a first bank address signal BA<0> to successively increase or decrease the logic value of a first refresh address signal Ref_Gax_BK0. The first bank refresh counter 210 generates the first refresh address signal Ref_Gax_BK0 in response to the refresh signal REFP and the first bank address signal BA<0> which are enabled during a refresh operation. In other words, the first bank refresh counter 210 generates the first refresh address signal Ref_Gax_BK0 when the first bank address signal BA<0> selects a first memory bank during the refresh operation. The refresh signal REFP is a signal which is enabled during the refresh operation of the semiconductor apparatus, and may be generated from an external command signal.

The second bank refresh counter 220 is configured to receive the refresh signal REFP and a second bank address signal BA<1> to successively increase or decrease the logic value of a second fresh address signal Ref_Gax_BK1. The second bank refresh counter 220 generates the second refresh address signal Ref_Gax_BK1 in response to the refresh signal REFP and the second bank address signal BA<1> which are enabled during a refresh operation. In other words, the second bank refresh counter 220 generates the second refresh address signal Ref_Gax_BK1 when the second bank address signal BA<1> selects a second memory bank during the refresh operation.

The second and third bank refresh counters 230 and 240 may also be configured to receive the refresh signal REFP and third and fourth bank address signals BA<2:3>, respectively, to successively increase or decrease third and fourth refresh address signals Ref_Gax_BK2 and Ref_Gax_BK3, respectively, in a similar manner as the first and second bank refresh counters 210 and 220.

The first bank selection unit 510 is configured to generate a first bank select signal ACT_BK0 in response to the first bank address signal BA<0> during a refresh operation. The second bank selection unit 520 is configured to generate a second bank select signal ACT_BK1 in response to the second bank address signal BA<1> during the refresh operation. The third bank selection unit 530 is configured to generate a third bank select signal ACT_BK2 in response to the third bank address signal BA<2> during the refresh operation. The fourth bank selection unit 540 is configured to generate a fourth bank select signal ACT_BK3 in response to the fourth bank address signal BA<3> during the refresh operation.

The row selection unit 600 is configured to receive the first to fourth refresh address signals Ref_Gax_BK0 to Ref_Gax_BK3 and the first to fourth bank select signals ACT_BK0 to ACT_BK3 to generate first to fourth row select signals Row_BK0 to Row_BK3. The first to fourth row select signals Row_BK0 to Row_BK3 are signals for enabling word lines of the corresponding memory banks, respectively. When receiving the refresh address signals Ref_Gax_BK0 to Ref_Gax_BK3 for a memory bank which is designated by an enabled bank select signal comprising of the first to fourth bank select signals ACT_BK0 to ACT_BK3, the row selection unit 600 generates the row select signals Row_BK0 to Row_BK3. When only the first bank select signal ACT_BK0 is enabled and the first refresh address signal Ref_Gax_BK0 is inputted, the row selection unit 600 enables the first row select signal Row_BK0, and disables the second to fourth row select signals Row_BK1 to Row_BK3. Similarly, when the first and second bank select signals ACT_BK0 and ACT_BK1 are enabled and the first and second refresh address signals Ref_Gax_BK0 and Ref_Gax_BK1 are inputted, the row selection unit 600 may enable the first and second row select signals Row_BK0 and Row_BK1.

The refresh control circuit of the semiconductor apparatus according to the embodiment may control a refresh operation to be performed for each memory bank. The refresh control circuit includes the same number of refresh counters as the memory banks, and the refresh counters are controlled by the bank address signals. Therefore, the refresh counters may be separately operated via the bank address signals during the refresh operation. Only a bank refresh counter enabled by a bank address signal may operate to provide a refresh address signal, in order for a refresh operation for a memory bank selected by the bank address signal may be separately performed.

Unlike the conventional semiconductor apparatus, the refresh control circuit of the semiconductor apparatus according to the embodiment, which controls a refresh operation to be performed for a specific memory bank, has the following advantage. A refresh operation does not need to be immediately performed on a memory bank in which a normal operation, i.e., a read or write operation, was performed. When a refresh operation is immediately performed on all memory banks including the memory bank in which the read or write operation was performed, current consumption unnecessarily increases. Therefore, since the refresh control circuit according to the embodiment may control a specific memory bank to separately perform a refresh operation, unnecessary current consumption may be reduced.

Additionally, a memory bank which does not perform a refresh operation may perform a normal operation. In other words, memory banks may separately perform a refresh and non-refresh operation concurrently, thereby maximizing efficiency. As a result, it is possible to increase the bandwidth of the semiconductor apparatus.

In FIG. 2, the refresh control circuit may further include an address latch unit 10, an address selection unit 300, and an activation control unit 40. The address latch unit 10 is configured to receive a row address signal RA and an active signal ACT to generate a normal address signal Normal_Gax. The active signal ACT is a signal to indicate a normal operation of the semiconductor apparatus, and may be generated from an external command signal.

The address selection unit 300 receives the normal address signal Normal_Gax from the address latch unit 10, and receives the first to fourth refresh address signals Ref_Gax_BK0 to Ref_Gax_BK3 from the first to fourth bank refresh counters 210 to 240. Generally, the address selection unit 300 selectively provides the normal address signal Normal_Gax and/or the first to fourth refresh address signals Ref_Gax_BK0 to Ref_Gax_BK3 as the output address signal Gax depending on an enabled or disabled refresh command REF. Specifically, the address selection unit 300 provides the normal address signal Normal_Gax as the output address signal Gax when the refresh command REF is disabled, and provides the first to fourth refresh address signals Ref_Gax_BK0 to Ref_Gax_BK3 as the output address signal Gax when the refresh command REF is enabled. The refresh command REF is a signal that designates a refresh operation of the semiconductor apparatus, and may be generated from an external command signal.

The activation control unit 40 is configured to generate an activation control signal ACTCON to enable the first to fourth bank selection units 510 to 540. The activation control unit 40 enables the activation control signal ACTCON when any one of the active signal ACT and the refresh signal REFP is enabled.

During a normal operation, the address selection unit 300 provides the normal address signal Normal_Gax outputted from the address latch unit 10 as the output address signal Gax in response to a disabled refresh command REF. The first to fourth bank selection units 510 to 540 enable the first to fourth bank select signals ACT_BK0 to ACT_BK3 in response to the first to fourth bank address signals BA<0:3>, respectively. The row selection unit 600 combines the output address signal Gax based on the normal address signal Normal_Gax and the bank select signals ACT_BK0 to ACT_BK3 based on the bank address signals BA<0:3>, to generate the first to fourth row select signals Row_BK0 to Row_BK3. Therefore, a word line is enabled in the memory banks via the normal address signal Normal_Gax and bank address signals BA<0:3>.

During a refresh operation, the address selection unit 300 provides the first to fourth refresh address signals Ref_Gax_BK0 to Ref_Gax_BK3 outputted from the first to fourth bank refresh counters 210 to 240 as the output address signal Gax in response to the enabled refresh command REF. Concurrently, the refresh address signals for the memory banks selected according to the bank address signals BA<0:3> may be separately generated. The first to fourth bank selection units 510 to 540 enable the first to fourth bank select signals ACT_BK0 to ACT_BK3 in response to the bank address signals BA<0:3>, respectively. The row selection unit 600 combines the output address signal Gax based on the bank address signals BA<0:3>, the refresh address signals Ref_Gax_BK0 to Ref_Gax_BK3, and the bank select signals ACT_BK0 to ACT_BK3 based on the bank address signals BA<0:3>, to generate the first to fourth row select signals Row_BK0 to Row_BK3. Therefore, word lines may be enabled in the memory banks via the refresh address signals Ref_Gax_BK0 to Ref_Gax_BK3 selected by the bank address signals BA<0:3>. Thus, only the selected memory banks may separately perform a refresh operation.

While certain embodiments have been described above, it will be understood to those skilled in the art that the embodiments described are by way of example only. Accordingly, the refresh control circuit and method described herein should not be limited based on the described embodiments. Rather, the refresh control circuit and method described herein should only be limited in light of the claims that follow when taken in conjunction with the above description and accompanying drawings.

What is claimed is:

1. A refresh control circuit semiconductor apparatus, comprising:
a first bank refresh counter configured to increase or decrease a logic value of a first refresh address signal when a first bank address signal is enabled during a refresh operation;
a second bank refresh counter configured to increase or decrease a logic value of a second refresh address signal when a second bank address signal is enabled during the refresh operation;
a bank selection unit configured to generate first and second bank select signals in response to the first and second bank address signals during the refresh operation; and
a row selection unit configured to generate first and second row select signals in response to the first and second refresh address signals and the first and second bank select signals.

2. The refresh control circuit according to claim 1, wherein the row selection unit generates the first row select signal according to the first refresh address signal, when the first bank select signal is enabled.

3. The refresh control circuit according to claim 2, wherein the row selection unit disables the second row select signal according to the first refresh address signal, when the first bank select signal is enabled.

4. The refresh control circuit according to claim 1, wherein the row selection unit generates the second row select signal according to the second refresh address signal, when the second bank select signal is enabled.

5. The refresh control circuit according to claim 4, wherein the row selection unit disables the first row select signal according to the second refresh address signal, when the second bank select signal is enabled.

6. A refresh control circuit semiconductor apparatus,
wherein during a normal operation, the refresh control circuit enables word lines of a specific memory bank in response to a bank address signal and a row address signal, and
wherein during a refresh operation, the refresh control circuit selects a specific memory bank in response to the bank address signal, by enabling word lines included in the selected memory bank in response to a refresh address signal.

7. A method of operating a refresh control semiconductor apparatus, comprising the steps of:
generating a refresh address signal for a specific memory bank among a plurality of memory banks in response to a bank address signal during a refresh operation;
enabling a bank select signal for the specific memory bank in response to the bank address signal during the refresh operation; and
combining the refresh address signal and the bank select signal to generate a row address signal.
